(19) United States
(12) Patent Application Publication
(10) Pub. No.: US 2025/0089445 A1
(43) Pub. Date: Mar. 13, 2025

(54) LIGHT-EMITTING ELEMENT AND DISPLAY DEVICE

(71) Applicant: SHARP KABUSHIKI KAISHA, Sakai City, Osaka (JP)

(72) Inventors: SHINICHI HANDA, Sakai City, Osaka (JP); YUSUKE SAKAKIBARA, Sakai City, Osaka (JP)

(21) Appl. No.: 18/580,740

(22) PCT Filed: Sep. 16, 2021
(86) PCT No.: PCT/JP2021/034172

§ 371 Date: Jan. 19, 2024

(51) Int. Cl. H10K 50/165; H10K 50/115; H10K 50/125; H10K 59/38

(52) U.S. Cl. CPC H10K 50/165; H10K 50/115; H10K 50/125; H10K 59/38

(57) ABSTRACT

A light-emitting element includes a light-emitting layer including first quantum dots and second quantum dots, the electron transport layer includes a first material having a first particle size distribution and a second material having a second particle size distribution different from the first particle size distribution, an electron affinity of a first light-emitting material is equal to or smaller than an electron affinity of the first material, an electron affinity of the second material is smaller than the electron affinity of the first material, and an electron affinity of a second light-emitting material is equal to or smaller than the electron affinity of the second material.

### TECHNICAL FIELD

The disclosure relates to a light-emitting element including a light-emitting layer including a mixture of a first light-emitting material that emits light having a first wavelength and a second light-emitting material that emits light having a second wavelength different from the first wavelength, and a display device.

### BACKGROUND ART

In the related art, a light-emitting element including a light-emitting layer including a mixture of a first quantum dot that emits red light, a second quantum dot that emits green light, and a third quantum dot that emits blue light is known (PTL 1). The light-emitting element emits light by transmitting any one of red light, green light, and blue light through a color filter formed above the light-emitting layer.

### CITATION LIST

### Patent Literature

PTL 1: WO 2019/180877 Pamphlet

### SUMMARY

### Technical Problem

However, in the light-emitting element described in PTL 1, electron affinities of the quantum dots are different for the different emission colors, and thus the electron affinities of electron transport layers capable of efficiently injecting electrons into the quantum dots are also different. Thus, when an electron transport layer is formed of a material having a single electron affinity, there is a problem in that the overall luminous efficiency of red light, green light, and blue light cannot be increased.

An object of one aspect of the disclosure is to provide a light-emitting element capable of increasing the overall luminous efficiency of light having a first wavelength and light having a second wavelength different from the first wavelength, and a display device.

### Solution to Problem

In order to solve the above-described problems, a light-emitting element according to an aspect of the disclosure includes a light-emitting layer including a mixture of a first light-emitting material configured to emit light having a first wavelength and a second light-emitting material configured to emit light having a second wavelength different from the first wavelength, and an electron transport layer, in which the electron transport layer includes a first material having a first particle size distribution and a second material having a second particle size distribution different from the first particle size distribution, includes a first material and a second material that are composed of A₁₋ₓBₓC (0≤x<1, and A, B, and C are a first element, a second element, and a third element being different from each other) and have mutually different compositions (x), or includes a first material and a second material having mutually different constituent elements, an electron affinity of the first light-emitting material is equal to or smaller than an electron affinity of the first material, an electron affinity of the second material is smaller than the electron affinity of the first material, and an electron affinity of the second light-emitting material is equal to or smaller than the electron affinity of the second material.

In order to solve the above-described problems, another light-emitting element according to an aspect of the disclosure includes a light-emitting layer including a mixture of a first light-emitting material configured to emit light having a first wavelength and a second light-emitting material configured to emit light having a second wavelength different from the first wavelength, and an electron transport layer, in which the electron transport layer includes a first material having a first particle size distribution and a second material having a second particle size distribution different from the first particle size distribution, includes a first material and a second material that are composed of Zn₁₋ₓMgₓO (0≤x<1) and have mutually different compositions (x), or includes a combination of a first material and a second material having mutually different constituent elements, and
the combination of the first material and the second material having mutually different constituent elements includes two different combinations selected from (1) at least one selected from TiO₂ and SnO₂, (2) at least one selected from GaP, AlSb, and ZrO₂, and (3) at least one selected from GaN, ZnS, ZnTe, Ca₂SnO₄, and CaSnO₃.

In order to solve the above-described problems, still another light-emitting element according to an aspect of the disclosure includes a light-emitting layer including a mixture of a first light-emitting material configured to emit light having a first wavelength and a second light-emitting material configured to emit light having a second wavelength different from the first wavelength, and a hole transport layer, in which the hole transport layer includes a first material and a second material, an ionization potential of the first light-emitting material is equal to or larger than an ionization potential of the first material, an ionization potential of the second material is larger than the ionization potential of the first material, and an ionization potential of the second light-emitting material is equal to or larger than the ionization potential of the second material.

In order to solve the above-described problems, another display device according to an aspect of the disclosure includes a plurality of the light-emitting elements according to the aspect of the disclosure, in which the plurality of light-emitting elements further include anodes, cathodes, and side walls, the side walls being disposed between adjacent cathodes of the plurality of light-emitting elements and capable of separating the adjacent cathodes, or being disposed between adjacent anodes of the plurality of light-emitting elements and capable of separating the adjacent anodes.

In order to solve the above-described problems, still another display device according to an aspect of the disclosure includes a plurality of the light-emitting elements according to the aspect of the disclosure, in which the plurality of light-emitting elements further include anodes, cathodes, and side walls, the side walls being disposed between adjacent light-emitting elements and capable of separating the adjacent light-emitting elements.

### Advantageous Effects of Disclosure

According to one aspect of the disclosure, it is possible to provide a light-emitting element capable of increasing the overall luminous efficiency of light having a first wavelength and light having a second wavelength different from the first wavelength, and a display device.

### BRIEF DESCRIPTION OF DRAWINGS

FIG. 1 is a cross-sectional view of a light-emitting element according to a first embodiment.

FIG. 2 is a diagram illustrating a flow of electrons injected into a light-emitting layer provided in the light-emitting element.

FIG. 3 is a diagram illustrating injection of electrons into a light-emitting layer from an electron transport layer provided in the light-emitting element.

FIG. 4 is a circuit diagram of an equivalent circuit related to injection of electrons into the light-emitting layer from the electron transport layer.

FIG. 5 is a diagram illustrating an injection barrier of electrons into the light-emitting layer from the electron transport layer.

FIG. 6 is a diagram illustrating an image in which electrons are injected into the light-emitting layer from the electron transport layer.

FIG. 7 is a graph showing a relationship between a particle radius of a material of the electron transport layer, a band gap, and an electron affinity.

FIG. 8 is a graph showing a relationship between a composition of a material of the electron transport layer and an electron affinity.

FIG. 9 is a cross-sectional view of a display device according to a modified example of the first embodiment.

FIG. 10 is a cross-sectional view of a light-emitting element according to a second embodiment.

FIG. 11 is a diagram illustrating an electron level of the light-emitting layer provided in the light-emitting element according to the first embodiment.

FIG. 12 is a diagram illustrating an electron level of a light-emitting layer provided in the light-emitting element according to the second embodiment.

FIG. 13 is a diagram illustrating an injection barrier of holes from a hole transport layer to the light-emitting layer provided in the light-emitting element.

FIG. 14 is a cross-sectional view of a display device according to a modified example of the second embodiment.

### DESCRIPTION OF EMBODIMENTS

### First Embodiment

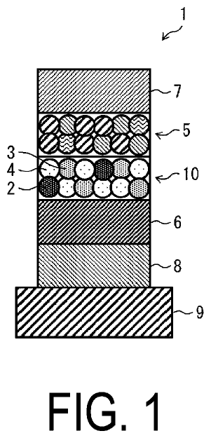

FIG. 1 is a cross-sectional view of a light-emitting element 1 according to a first embodiment. An anode 8, a hole transport layer 6, a light-emitting layer 10, an electron transport layer 5, and a cathode 7 are provided in this order on a substrate 9. The light-emitting layer 10 includes a mixture of first quantum dots 2 (first light-emitting material) that emit red light (light having a first wavelength), second quantum dots 3 (second light-emitting material) that emit green light (light having a second wavelength), and third quantum dots 4 (third light-emitting material) that emit blue light. The light-emitting layer 10 can emit white light including the three wavelengths of red, green, and blue. Here, the light-emitting layer 10 includes a mixture of three types of quantum dots, but may include a mixture of two types of quantum dots.

Here, the quantum dot means a dot with a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

In this manner, the light-emitting layer 10 includes a mixture of the first quantum dots 2 that emit light having a first wavelength and the second quantum dots 3 that emit light having a second wavelength different from the first wavelength. Here, in the case of different wavelengths, two wavelength ranges do not need to be completely separated from each other and may be overlapping wavelength ranges. As a result of measuring an emission wavelength from the light-emitting layer 10 including the first and second quantum dots 2 and 3, when at least two emission peaks can be confirmed, it is assumed that the light-emitting layer 10 emits light having two different wavelengths.

The anode 8 includes a conductive material and is electrically connected to the hole transport layer 6. The cathode 7 includes a conductive material and is electrically connected to the electron transport layer 5.

At least one of the anode 8 and the cathode 7 is constituted by a transparent conductive film. As the transparent conductive film, for example, ITO, IZO, ZnO, AZO, BZO, and the like, or Ag, Al, Cu, Au, and the like formed into thin layers, nanoparticles, or nanowires are used. The transparent conductive film can be formed by a sputtering method, vapor deposition, coating, or the like.

Either one of the anode 8 and the cathode 7 may be formed of a metal. The metal is preferably Al, Cu, Au, Ag, or the like having a high reflectivity of visible light.

The hole transport layer 6 is formed of a p-type oxide semiconductor (for example, NiO, MgNiO, Cu₂O) or an organic material such as PEDOT:PSS/PVK. The hole transport layer 6 can be formed by coating, a sputtering method, vapor deposition, or the like.

For the first quantum dots 2, the second quantum dots 3, and the third quantum dots 4, a core/shell structure such as CdSe/CdS, CdSe/ZnS, InP/ZnS, ZnSe/ZnS, or CIGS/ZnS can be used. The particle size of each of the quantum dots 2, 3, and 4 is typically approximately 3 nm to 10 nm. The light-emitting layer 10 is formed using a mixed solution in which the respective quantum dots 2, 3, and 4 are mixed and dispersed in a solvent such as hexane by a spin coating method, an ink-jet method, or the like. Nanoparticles composed of inorganic materials can make the reliability of the light-emitting layer higher than that with organic materials.

The first quantum dots 2, the second quantum dots 3, and the third quantum dots 4 can change the wavelength of emitted light in accordance with particle sizes and materials of the cores of the quantum dots. When the materials are the same, the smaller the particle size of the core is, the shorter the wavelength of emitted light is.

In the light-emitting layer 10, the first quantum dots 2, the second quantum dots 3, and the third quantum dots 4 may have any distribution or arrangement. However, it is preferable that the first quantum dots 2, the second quantum dots 3, and the third quantum dots 4 be randomly distributed. A uniform light-emitting element 1 can be obtained without causing color unevenness. Further, it is preferable that the quantum dots with a shorter emission wavelength have a higher distribution proportion. Quantum dots having a shorter emission wavelength have a lower luminous efficiency and increasing their distribution proportion makes it easier to emit white light.

The electron transport layer 5 is a mixture of nanoparticles having two or more different electron affinities. When three types of quantum dots are included in the light-emitting layer 10, the number of electron affinities is three, and it is preferable that the electron transport layer 5 be a mixture of three types of nanoparticles having three electron affinities. Thereby, the electron transport layer 5 can efficiently inject electrons into each of the three types of quantum dots being the first quantum dots 2, the second quantum dots 3, and the third quantum dots 4, and thus the overall luminous efficiency can be increased. The nanoparticles of the electron transport layer 5 are composed of an inorganic compound, and thus it is possible to increase reliability.

The electron transport layer 5 includes a first material having a first particle size distribution and a second material having a second particle size distribution different from the first particle size distribution. For example, the electron transport layer 5 includes a first material having a particle size distribution within approximately +15% around a particle size of 12 nm and a second material having a particle size distribution within approximately +15% around a particle size of 4 nm.

Here, the “particle size” is a diameter of a circle having an area corresponding to an area of a particle confirmed in observation of a cross-section of a layer including particles. The “different particle size distribution” means that two particle size distributions do not need to be completely separated from each other and may have overlapping particle size ranges. As a result of observing the cross-section of the electron transport layer 5 including the first material and the second material, when at least two particle size peaks can be confirmed, it is assumed that the electron transport layer 5 includes particles having two different particle size distributions.

The electron transport layer 5 may be composed of Zn₁₋ₓMgₓO (0≤x<1) and may include a first material and a second material having different compositions (x). The electron transport layer 5 may include a first material and a second material each including any one of at least one selected from TiO₂ and SnO₂, at least one selected from GaP, AlSb, and ZrO₂, or at least one selected from GaN, ZnS, ZnTe, Ca₂SnO₄, and CaSnO₃.

The electron transport layer 5 further includes a third material having a third particle size distribution different from the first particle size distribution and the second particle size distribution. For example, the electron transport layer 5 includes a first material having a particle size distribution of less than approximately +15% around a particle size of 12 nm, a second material having a particle size distribution of less than approximately +15% around a particle size of 4 nm, and a third material having a particle size distribution of less than approximately +15% around a particle size of 3 nm.

The electron transport layer 5 may include a third material composed of Zn₁₋ₓMgₓO (0≤x<1) and having a composition (x) different from that of the first material and the second material, or may include a first material including at least one selected from TiO₂ and SnO₂, a second material including at least one selected from GaP, AlSb, and ZrO₂, and a third material including at least one selected from GaN, ZnS, ZnTe, Ca₂SnO₄, and CaSnO₃.

It is preferable that the electron transport layer 5 be a mixture of three types of ZnO nanoparticles having particle sizes of, for example, 12 nm, 4 nm, and 3 nm. Thereby, the electron transport layer 5 can have an electron affinity that increases the luminous efficiency of each of the three types of quantum dots being the first quantum dots 2, the second quantum dots 3, and the third quantum dots 4. In general, when the particle size of the nanoparticles is reduced, the band gap widens due to the quantum effect, and the electron affinity decreases. The ZnO nanoparticles having particle sizes of 12 nm, 4 nm, and 3 nm have electron affinities of 3.9 eV, 3.5 eV, and 3.1 eV, respectively, and are mixed to realize the electron transport layer 5 having the three electron affinities.

Here, the nanoparticles having an average particle size of 12 nm are nanoparticles having a variation of less than approximately ±15% around 12 nm, and particles within that variation in particle size are not said to have different electron affinities.

The three types of nanoparticles of the electron transport layer 5 are of the same material, and thus, can be easily prepared by having their synthesis time adjusted. In addition, they have the same crystal structure, and thus, an electrical conductivity and the like are not significantly changed.

In order to impart different electron affinities, for example, in Zn₁₋ₓMgₓO (0≤x<1), the composition can be changed with x=0, 0.2, 0.4 to realize the three types of nanoparticles of the electron transport layer 5, or different materials, such as TiO₂, may be used to realize the three types of nanoparticles. Alternatively, the particle size and composition may be changed simultaneously to realize the three types of nanoparticles.

Each of the nanoparticles is prepared by a known technique, and a mixed solution in which the nanoparticles are mixed in an organic solvent such as ethanol is used to form the electron transport layer 5 using a spin coating method, an ink-jet method, or the like.

In the present embodiment, the light-emitting layer 10 includes a mixture of the first quantum dots 2, the second quantum dots 3, and the third quantum dots 4 of three colors RGB, and the electron affinities of the respective quantum dots are QD1=3.6 eV, QD2=3.3 eV, and QD3=2.9 eV. In addition, the electron transport layer 5 is a mixture of ZnO nanoparticles having average particle sizes of 12 nm, 4 nm, and 3 nm, and the electron affinities thereof are set to 3.9 eV (ETL1), 3.5 eV (ETL2), and 3.1 eV (ETL3) in descending order.

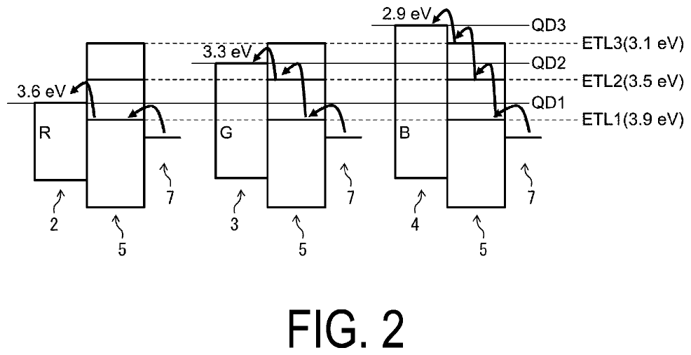

FIG. 2 is a diagram illustrating a flow of electrons injected into each of the first quantum dot 2, the second quantum dot 3, and the third quantum dot 4 of the light-emitting element 1.

FIG. 2 illustrates a band diagram between the first quantum dot 2, the second quantum dot 3, and the third quantum dot 4 according to the first embodiment and the cathode 7, and arrows representing a flow of electrons injected into the first quantum dot 2, the second quantum dot 3, and the third quantum dot 4 from the cathode 7. The electrons are injected in order from the one having a large electron affinity to the one having a small electron affinity as voltage is applied.

The electron transport layer 5 has the three electron affinities ETL1, ETL2, and ETL3, and when a voltage is applied between the anode 8 and the cathode 7, electrons are first injected into the location of the electron transport layer 5 having the largest electron affinity ETL1 from the cathode 7. Then, the electrons are injected into the location of the electron transport layer 5 having the second largest electron affinity ETL2 from the location of the electron affinity ETL1. Next, the electrons are injected into the location of the electron transport layer 5 having the smallest electron affinity ETL3 from the location of the electron affinity ETL2.

For the first quantum dots 2 having an electron affinity QD1, electrons are first injected into the location of the electron affinity ETL1 from the cathode 7. Then, the electrons can be injected into the first quantum dots 2 having the electron affinity QD1 from the location of the electron affinity ETL1 before being injected into the location of the electron affinity ETL2.

For the second quantum dots 3 having an electron affinity QD2, electrons are first injected into the location of the electron affinity ETL1 from the cathode 7. Then, the electrons are injected into the location of the electron affinity ETL2 from the location of the electron affinity ETL1. Next, the electrons can be injected into the second quantum dots 3 having the electron affinity QD2 from the location of the electron affinity ETL2 before being injected into the location of the electron affinity ETL3.

For the third quantum dots 4 having an electron affinity QD3, electrons are first injected into the location of the electron affinity ETL1 from the cathode 7. Then, the electrons are injected into the location of the electron affinity ETL2 from the location of the electron affinity ETL1. Next, after electrons are injected into the location of the electron affinity ETL3 from the location of the electron affinity ETL2, the electrons can be injected into the third quantum dots 4 having the electron affinity QD3.

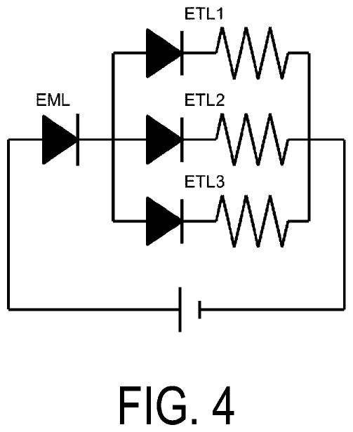

In this manner, electrons are injected into the first quantum dots 2, the second quantum dots 3, and the third quantum dots 4 from the locations of appropriate electron affinities ETL1, ETL2, and ETL3 with high luminous efficiency. Almost no electrons are injected from other locations of ETL. This will be described using a circuit diagram of FIG. 4.

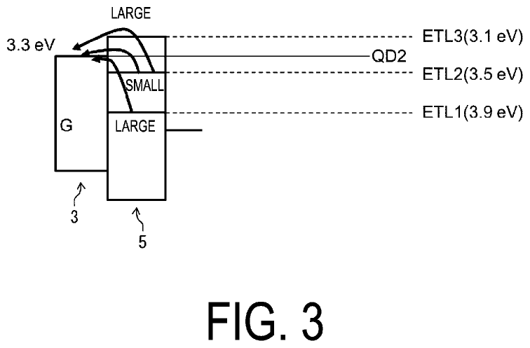

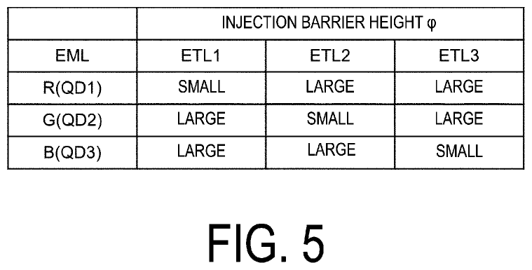

FIG. 3 is a diagram illustrating injection of electrons into the second quantum dots 3 from the electron transport layer 5 provided in the light-emitting element 1. FIG. 4 is a circuit diagram of an equivalent circuit related to injection of electrons into the light-emitting layer (the first quantum dots 2, the second quantum dots 3, or the third quantum dots 4) from the electron transport layer 5. FIG. 5 is a diagram illustrating an injection barrier of electrons into the first quantum dots 2, the second quantum dots 3, and the third quantum dots 4 from the electron transport layer 5.

When injection of electrons into the light-emitting layer 10 from the electron transport layer 5 is illustrated in the circuit diagram, the electron transport layer 5 can be indicated such that three series circuits each having a diode and a resistor are disposed in parallel as illustrated in FIG. 4.

A current of the diode can be represented as follows.

$$I = I 0 [ exp \{ q ( V - φ ) / nkT \} - 1 ]$$

Here, φ corresponds to an injection barrier height of the diode, and its size correlates with an injection barrier from the electron transport layer 5 to the first quantum dots 2, second quantum dots 3, or the third quantum dots 4. The current I of the diode increases exponentially with respect to a voltage, the current I changes significantly due to the injection barrier height y, and most of the current flows to a diode having a small injection barrier height y.

For example, as illustrated in FIG. 3, a case is considered in which electrons are injected up to the electron affinity QD2 of the second quantum dot 3 when the electrons are injected into the second quantum dots 3 emitting green light from the electron transport layer 5. An injection barrier from the electron affinities ETL1, ETL2, and ETL3 of the electron transport layer 5 is 0.6 eV when electrons are injected from the electron affinity ETL1 (3.9 eV) to the electron affinity QD2 (3.3 eV), and is 0.2 eV when electrons are injected from the electron affinity ETL2 (3.5 eV) to the electron affinity QD2 (3.3 eV). In the case of the electron affinity ETL3, an injection barrier is 0.4 eV because electrons pass from the electron affinity ETL2 (3.5 eV) to the electron affinity ETL3 (3.1 eV). In this manner, since an injection barrier from the electron affinity ETL2 is the smallest, electrons are mostly injected into the second quantum dot 3 from the electron affinity ETL2.

The same applies to the other first quantum dots 2 and third quantum dots 4, and a magnitude relationship of an injection barrier height p is as illustrated in FIG. 5.

When the electron transport layer 5 has a plurality of electron affinities ETL1, ETL2, and ETL3, electrons can be injected into each of the first quantum dot 2, the second quantum dot 3, and the third quantum dot φ of RGB from the electron transport layer 5 at an appropriate low voltage, as compared to a case where a single electron affinity is used for the electron transport layer 5.

Thus, the first quantum dots 2, the second quantum dots 3, and the third quantum dots 4 can each efficiently emit light within the light-emitting layer 10 by including a mixture in the electron transport layer 5 that is a mixture prepared such that nanoparticles, which have an electron affinity that increases injection efficiency for each of the first quantum dots 2, the second quantum dots 3, and the third quantum dots 4 that emit light with different emission wavelengths, are appropriately selected and mixed as a first material, a second material, and a third material.

For this reason, it is preferable that the electron transport layer 5 have the same number of different electron affinities as the number of colors of light emitted by the quantum dots included in the light-emitting layer 10. In the case of three colors, when the electron affinities of the first quantum dots 2, the second quantum dots 3, and the third quantum dots 4 are assumed to be an electron affinity QD1, an electron affinity QD2, and an electron affinity QD3 in descending order, and the electron affinities of the electron transport layer 5 are assumed to be an electron affinity ETL1, an electron affinity ETL2, and an electron affinity ETL3 in descending order, the following relationship is preferred.

QD3≤ETL3<QD2≤ETL2<QD1≤ETL1

Electrons can be injected from electron affinities suitable for the quantum dots of the respective emission colors, and the luminous efficiency of the quantum dots of the respective emission colors can be increased, resulting in a higher luminous efficiency as a whole.

In addition, for every 0.1 eV difference in electron affinity, the ease of injection of a current varies by approximately 50 times, and thus a difference in electron affinity between the nanoparticles of the first material, the second material, and the third material is preferably 0.1 eV or more. A current can be preferentially applied to suitable quantum dots among the first quantum dots 2, the second quantum dots 3, and the third quantum dots 4. Furthermore, since a difference in electron affinity between the first quantum dots 2, the second quantum dots 3, and the third quantum dots 4 of RGB varies by 0.3 eV or more, when a difference in electron affinity of nanoparticles is 0.3 eV or more, the electron transport layer 5 can be provided with nanoparticles that increase injection efficiency with respect to the first quantum dots 2, the second quantum dots 3, and the third quantum dots 4 of the respective colors.

In Zn₁₋ₓMgₓO, the larger the value of x, generally, the smaller the electron affinity, so electron concentration is lower and resistivity is higher. In general, the luminous efficiency of the quantum dots decreases in the order of RGB (in the order in which the electron affinity decreases). For this reason, by increasing a volume ratio of nanoparticles with a smaller electron affinity, electrons can be more easily injected into the nanoparticles with a smaller electron affinity, and the luminous efficiency of colors with a lower luminous efficiency can be improved. Thus, the overall luminous efficiency of the light-emitting element 1 can be enhanced in a well-balanced manner. In addition, electrons are easily injected into nanoparticles having a large electron affinity from the cathode 7, and thus it is preferable that the nanoparticles having a large electron affinity have the largest volume ratio in the vicinity of the interface with the cathode 7. Thereby, electrons are easily injected into the electron transport layer 5 from the cathode 7. The volume ratio of the nanoparticles having a large electron affinity at the interface with the cathode 7 may be 100%.

In the present specification, the vicinity of the interface indicates a portion within 30 nm from the interface.

As for a material having the electron affinity ETL1, a material having the electron affinity ETL2, and a material having the electron affinity ETL3 of the electron transport layer 5, mutually different materials can be used. For example, as a material having the electron affinity ETL1, TiO₂ (an electron affinity of 4.2 eV) or SnO₂ (an electron affinity of 4.2 eV) can be used. As a material having the electron affinity ETL2, GaP (an electron affinity of 3.5 eV), AlSb (an electron affinity of 3.4 eV), or ZrO₂ (an electron affinity of 3.4 eV) can be used. As a material having the electron affinity ETL3, GaN (an electron affinity of 3.2 eV), ZnS (an electron affinity of 3.2 eV), ZnTe (an electron affinity of 3.2 eV), Ca₂SnO₄ (an electron affinity of 3.0 eV), CaSnO₃ (an electron affinity of 3.2 eV), or the like can be used.

Here, an electron affinity and an ionization potential of each material are treated as the numbers shown in the following Table 1.

TABLE 1

| Material | Ionization potential (eV) | Electron affinity (eV) |
|---|---|---|
| TiO₂ | 7.4 | 4.2 |
| SnO₂ | 7.7 | 4.2 |
| GaP | 6.1 | 3.5 |
| AlSb | 5.3 | 3.4 |
| ZrO₂ | 9.0 | 3.4 |
| GaN | 7.2 | 3.2 |
| ZnS | 7.2 | 3.2 |
| ZnTe | 5.8 | 3.2 |
| Ca₂SnO₄ | 8.1 | 3.0 |
| CaSnO₃ | 8.0 | 3.2 |
| Cu₂O | 5.5 | 3.3 |
| NiO | 5.4 | 2.0 |
| LaNiO₃ | 6.0 | 3.7 |
| CdSe (Red) | 5.6 | 3.6 |
| CdSe (Green) | 5.6 | 3.3 |
| CdSe (Blue) | 5.6 | 2.9 |
| CdTe (Red) | 5.2 | 3.2 |
| InN (Red) | 6.5 | 4.5 |
| InP (Red) | 5.4 | 3.4 |
| InP (Green) | 5.4 | 3.1 |
| ZnSe (Blue) | 5.8 | 3.1 |

( ) is an emission color of quantum dots

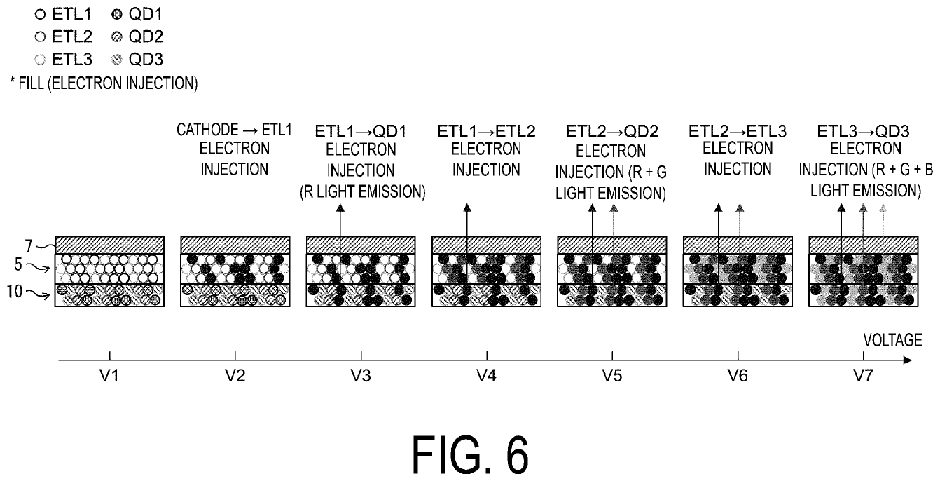

FIG. 6 is a diagram illustrating an image in which electrons are injected into the light-emitting layer 10 from the electron transport layer 5.

FIG. 6 illustrates a state where a voltage applied between the cathode 7 and the anode 8 is increased in order from the left.

First, in a case where a voltage V1 is applied between the cathode 7 and the anode 8, electrons are not injected into the electron transport layer 5 from the cathode 7. Next, in a case where the voltage V1 increases to a voltage V2, electrons are injected into the first material of the electron transport layer 5 having the electron affinity ETL1 from the cathode 7. Next, when the voltage V2 increases to a voltage V3, electrons are injected into the first quantum dots 2 from the first material of the electron transport layer 5 having the electron affinity ETL1, and the first quantum dots 2 emit red light.

Next, when the voltage V3 increases to a voltage V4, electrons are injected into the second material of the electron transport layer 5 having the electron affinity ETL2 from the first material of the electron transport layer 5 having the electron affinity ETL1. Then, when the voltage V4 increases to a voltage V5, electrons are injected into the second quantum dots 3 from the second material of the electron transport layer 5 having the electron affinity ETL2, and the second quantum dots 3 emit green light.

Next, when the voltage V5 increases to a voltage V6, electrons are injected into the third material of the electron transport layer 5 having the electron affinity ETL3 from the second material of the electron transport layer 5 having the electron affinity ETL2. Next, when the voltage V6 increases to a voltage V7, electrons are injected into the third quantum dots 4 from the third material of the electron transport layer 5 having the electron affinity ETL3, and the third quantum dots 4 emit blue light. Here, red light, green light and blue light are simultaneously emitted from the light-emitting layer 10 to emit white light.

In the vicinity of the interface between the cathode 7 and the electron transport layer 5, it is preferable that the first material of the electron transport layer 5 having the electron affinity ETL1 have a volume ratio larger than that of the second material of the electron transport layer 5 having the electron affinity ETL2, and it is preferable that the second material of the electron transport layer 5 having the electron affinity ETL2 have a volume ratio larger than that of the third material of the electron transport layer 5 having the electron affinity ETL3. It is more preferable that the first material of the electron transport layer 5 having the electron affinity ETL1 have a volume ratio of 100%. This is because electrons are more easily injected into the first material having the electron affinity ETL1 from the cathode 7 than the second material having the electron affinity ETL2.

In the vicinity of the interface between the electron transport layer 5 and the light-emitting layer 10, it is preferable that the third material of the electron transport layer 5 having the electron affinity ETL3 have a volume ratio larger than that of the second material of the electron transport layer 5 having the electron affinity ETL2, and it is preferable that the second material of the electron transport layer 5 having the electron affinity ETL2 have a volume ratio larger than that of the first material of the electron transport layer 5 having the electron affinity ETL1.

This is because, when the corresponding volume ratios of the third material, the second material, and the first material of the electron transport layer 5 are large in ascending order of the luminous efficiency of the third quantum dot 4 for blue light, the second quantum dot 3 for green light, and the first quantum dot 2 for red light, a balance of the luminous efficiency of the light-emitting element 1 can be improved.

It is preferable that the volume ratios of the third material of the electron transport layer 5 having the electron affinity ETL3 and the second material of the electron transport layer 5 having the electron affinity ETL2 gradually increase from the cathode 7 to the light-emitting layer 10, and that the volume ratio of the first material of the electron transport layer 5 having the electron affinity ETL1 decrease.

This is because there is no obstacle to electrons being injected into the second material having the electron affinity ETL2 from the first material having the electron affinity ETL1 and into the third material having the electron affinity ETL3 from the second material having the electron affinity ETL2 in a direction in which the electrons flow from the cathode 7 to the light-emitting layer 10, and a voltage in the electron transport layer 5 can be minimized.

The electron transport layer 5 including a mixture of the first material having the electron affinity ETL1, the second material having the electron affinity ETL2, and the third material having the electron affinity ETL3 can be formed by performing, for example, spin coating with a nanoparticle mixed solution of the second material and the third material (a volume ratio of the second material < the third material), and performing spin coating with a nanoparticle solution of the first material before drying.

Alternatively, the electron transport layer 5 including the mixture can be formed by preparing a plurality of solutions having different concentrations of the nanoparticle mixed solution of the first material, the second material, and the third material (proportions of the first material, the second material, and the third material) and applying the plurality of solutions a plurality of times to form layers, thereby having a concentration distribution in a layer thickness direction.

As described above, electrons are injected into the first quantum dots 2, the second quantum dots 3, and the third quantum dots 4 from the first material, the second material, and the third material having high injection efficiency, respectively, and thus luminous efficiency can be increased.

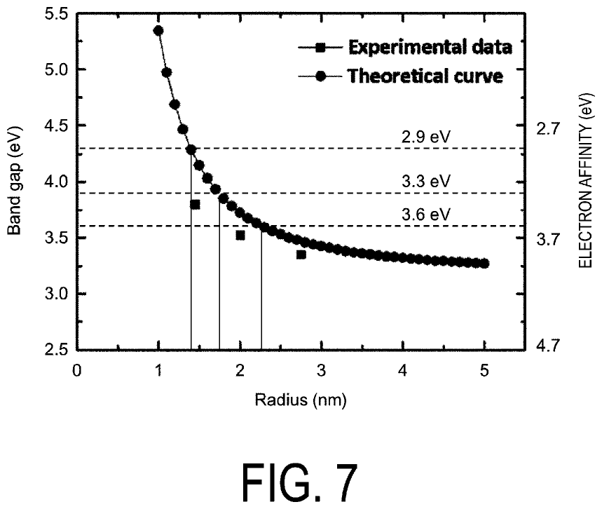

FIG. 7 is a graph showing a relationship between a radius of ZnO nanoparticles, a band gap, and an electron affinity.

It is preferable that the first material, the second material, and the third material of the mixture included in the electron transport layer 5 include nanoparticles and be composed of ZnO. When the particle size of the ZnO nanoparticles is reduced, the band gap widens due to a quantum effect, and the electron affinity decreases, and thus it is possible to realize the electron transport layer 5 having three types of electron affinities by changing the particle sizes of the first material, the second material, and the third material.

It is preferable that an average particle size of the nanoparticles of the first material be 4.5 nm or more. This is because, in this case, the radius of the nanoparticles of the first material is 2.25 nm or more, and as illustrated in FIG. 7, the electron affinity of the first material is 3.6 eV or more, which corresponds to the electron affinity of the first quantum dot 2.

It is preferable that the average particle size of the nanoparticles of the second material be 3.5 nm or more and less than 4.5 nm. This is because, in this case, the radius of the nanoparticles of the second material is 1.75 nm or more and 2.25 nm or less, and as illustrated in FIG. 7, the electron affinity of the second material is an electron affinity of 3.3 eV or more corresponding to the electron affinity of the second quantum dot 3, and an electron affinity of less than 3.6 eV corresponding to the electron affinity of the first quantum dot 2.

It is preferable that the average particle size of the nanoparticles of the third material be 2.8 nm or more and less than 3.5 nm. This is because, in this case, the radius of the nanoparticles of the third material is 1.4 nm or more and 1.75 nm or less, and as illustrated in FIG. 7, the electron affinity of the third material is an electron affinity of 2.9 eV or more corresponding to the electron affinity of the third quantum dot 4, and an electron affinity of less than 3.3 eV corresponding to the electron affinity of the second quantum dot 3.

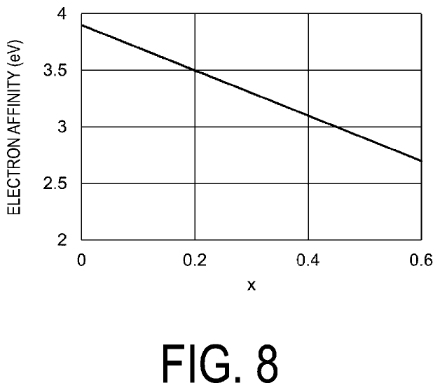

FIG. 8 is a graph showing a relationship between a composition x of Zn₁₋ₓMgₓO having an average particle size of 12 nm and an electron affinity.

The first material, the second material, and the third material of the mixture included in the electron transport layer 5 include nanoparticles having an average particle size of 12 nm, and preferably include Zn₁₋ₓMgₓO. When the composition x of Zn₁₋ₓMgₓO is changed, an electron affinity changes. For this reason, it is possible to realize the electron transport layer 5 having three types of electron affinities by varying the composition x between the first material, the second material, and the third material.

In the first material, x described above is preferably 0 or more and 0.15 or less. This is because, in this case, as illustrated in FIG. 8, the electron affinity ETL1 of the first material is larger than 3.6 eV, which is the electron affinity QD1 of the first quantum dot 2.

In the second material, x described above is preferably larger than 0.15 and 0.3 or less. This is because, in this case, as illustrated in FIG. 8, the electron affinity ETL2 of the second material is larger than 3.3 eV, which is the electron affinity QD2 of the second quantum dots 3, and is 3.6 eV or less, which is the electron affinity QD3 of the first quantum dot 2.

In the third material, x described above is preferably larger than 0.3 and 0.5 or less. This is because, in this case, as illustrated in FIG. 8, the electron affinity ETL3 of the third material is larger than 2.9 eV, which is the electron affinity QD3 of the third quantum dot 4, and is 3.3 eV or less, which is the electron affinity QD2 of the second quantum dot 3.

In this manner, the light-emitting element 1 includes the light-emitting layer 10 including a mixture of the first quantum dots 2 that emit red light having a first wavelength and the second quantum dots 3 that emit green light having a second wavelength different from the first wavelength, and the electron transport layer 5 that supplies electrons to the first quantum dots 2 and the second quantum dots 3.

The electron transport layer 5 includes a mixture of a first material and a second material. The electron affinity of the first quantum dot 2 is equal to or smaller than the electron affinity of the first material. The electron affinity of the second material is smaller than the electron affinity of the first material. The electron affinity of the second quantum dot 3 is equal to or smaller than the electron affinity of the second material.

It is preferable that the electron affinity of the first material and the electron affinity of the second material included in the electron transport layer 5 be different from each other by 0.1 eV or more. For every 0.1 eV difference in electron affinity, the ease of injection of a current varies by approximately 50 times, and thus a current can be preferentially applied to a material having an appropriate electron affinity.

It is preferable that the first material and the second material of the electron transport layer 5 each include an inorganic compound. It is possible to increase reliability by using an inorganic compound.

Quantum dots are more reliable than organic light-emitting materials, and can be easily formed using a coating method or an ink-jet method.

It is preferable that the light-emitting layer 10 further include the third quantum dots 4 that emit blue light having a third wavelength different from the first wavelength and the second wavelength.

The third material is further mixed into the mixture of the electron transport layer 5. The electron affinity of the third material is smaller than the electron affinity of the second material. The electron affinity of the third quantum dot 4 is equal to or smaller than the electron affinity of the third material.

It is preferable that the electron affinity of the first quantum dot 2 and the electron affinity of the second quantum dot 3 differ from each other. Thereby, the luminous efficiency of each of the first quantum dot 2 and the second quantum dot 3, which have mutually different electron affinities, can be increased by the electron transport layer 5.

When the electron affinity of the first quantum dot 2 is equal to or larger than the electron affinity of the second quantum dot 3, it is preferable that the electron affinity of the first material be equal to or larger than the electron affinity of the first quantum dot 2, the electron affinity of the first quantum dot 2 be equal to or larger than the electron affinity of the second material, and the electron affinity of the second material be equal to or larger than the electron affinity of the second quantum dot 3. Thereby, the luminous efficiency of each of the first quantum dot 2 and the second quantum dot 3, which have mutually different electron affinities, can be increased by the electron transport layer 5 including the mixture of the first material and the second material.

It is preferable that the first material and the second material include nanoparticles. When the particle size of the nanoparticles is reduced, the band gap widens due to the quantum effect, and the electron affinity decreases. For this reason, it is possible to realize the electron transport layer 5 having a plurality of types of electron affinities by changing the particle sizes of the first material and the second material.

It is preferable that the first material and the second material be composed of Zn₁₋ₓMgₓO (0≤x<1) and have mutually different compositions (x) or mutually different particle sizes. When the particle size of the nanoparticles of Zn₁₋ₓMgₓO (0≤x<1) is reduced, the band gap widens due to a quantum effect, and the electron affinity decreases, and thus it is possible to realize the electron transport layer 5 having a plurality of types of electron affinities by changing the particle sizes of the first material and the second material.

The first material, the second material, and the third material include nanoparticles, and it is preferable that the volume ratios of the first material, the second material, and the third material included in the electron transport layer 5 become larger in ascending order of the electron affinities thereof. Thereby, it is possible to improve the luminous efficiency more easily for a color having a lower luminous efficiency by facilitating the injection of electrons into nanoparticles having a small electron affinity.

The first material, the second material, and the third material include nanoparticles, and it is preferable that the volume ratios of the first material, the second material, and the third material included in the electron transport layer 5 become larger in descending order of the electron affinities in the vicinity of the interface with the cathode 7. Thereby, electrons are easily injected into the electron transport layer 5 from the cathode 7.

The first material, the second material, and the third material include nanoparticles, and it is preferable that the volume ratios of the first material, the second material, and the third material included in the electron transport layer 5 become larger in ascending order of the electron affinities in the vicinity of the interface with the light-emitting layer 10. Thereby, it is possible to improve a balance of the luminous efficiency when there are a large number of materials for the electron transport layer 5 corresponding to emission colors in ascending order of the luminous efficiency of quantum dots.

The first material, the second material, and the third material include nanoparticles, and it is preferable that the nanoparticles having the largest electron affinity among the first material, the second material, and the third material decrease in size from the cathode 7 side toward the light-emitting layer 10 side. Thereby, there is no obstacle to electrons being injected in the order of the first material, the second material, and the third material in a direction in which the electrons flow, and a voltage in the electron transport layer 5 can be minimized.

It is preferable that the amount of nanoparticles other than the nanoparticles having the largest electron affinity increase from the cathode 7 side toward the light-emitting layer 10 side. Thereby, there is no obstacle to electrons being injected in the order of the first material, the second material, and the third material in a direction in which the electrons flow, and a voltage in the electron transport layer 5 can be minimized.

It is preferable that the first material, the second material, and the third material include at least one selected from TiO₂ and SnO₂, at least one selected from GaP, AlSb, and ZrO₂, and at least one selected from GaN, ZnS, ZnTe, Ca₂SnO₄, and CaSnO₃. Thereby, different materials are used for the first material, the second material, and the third material, and thus it is possible to realize the electron transport layer 5 having three types of electron affinities.

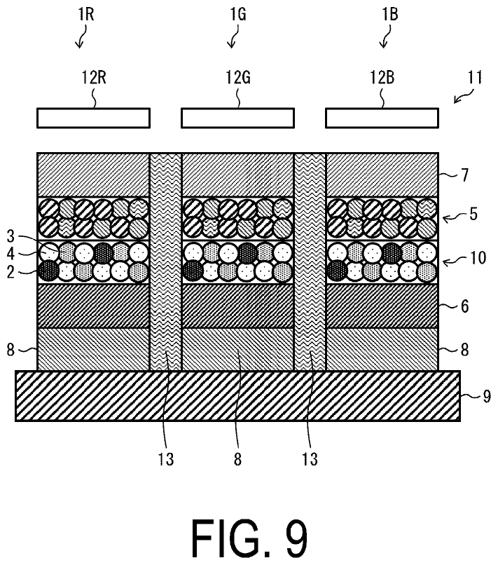

FIG. 9 is a cross-sectional view illustrating a display device 11 using the light-emitting element 1. The same constituent elements as the constituent elements described above are denoted by the same reference numerals and signs, and detailed descriptions thereof are not repeated. As illustrated in FIG. 9, the display device 11 includes a plurality of light-emitting elements 1R, 1G, and 1i, and color filters 12R, 12G, and 12B in light-emitting directions of the respective light-emitting elements 1R, 1G, and 1B. The color filters 12R, 12G, and 12B are filters that transmit only wavelengths of specific colors of light emitted from the light-emitting elements 1R, 1G, and 1B. More specifically, the color filter 12R transmits only red light, the color filter 12G transmits only green light, and the color filter 12B transmits only blue light. The light-emitting elements 1R, 1G, and 1B may or may not be separated from each other by side walls 13 as illustrated in FIG. 9.

Although an example in which the side walls 13 pass from the anode 8 to the cathode 7 to be able to separate the adjacent light-emitting elements 1R and 1G or 1G and 1B is shown, the disclosure is not limited thereto, and it is only required that the side walls 13 be formed being able to separate the adjacent anodes 8 from each other. Further, contrary to the example illustrated in FIG. 9, when the cathode 7, the electron transport layer 5, the light-emitting layer 10, the hole transport layer 6, and the anode 8 are layered on the substrate 9 in this order, it is only required that the side walls 13 be formed being able to separate the adjacent cathodes 7 from each other.

In the present embodiment, an example in which the electron affinities of the first quantum dots 2, the second quantum dots 3, and the third quantum dots 4 of three colors RGB are QD1=3.6 eV, QD2=3.3 eV, and QD3=2.9 eV, and in which the electron affinity of the quantum dots having a shorter emission wavelength is small, has been described, but the disclosure is not limited thereto. The disclosure can also be applied to a case where the electron affinity of the quantum dot that has the shorter emission wavelength is large. For example, when the first quantum dot 2 that emits red light includes CdTe, the second quantum dot 3 that emits green light includes CdSe, the third quantum dot 4 that emits blue light includes ZnSe, the electron affinities of the quantum dots are QD1=3.2 eV, QD2=3.3 eV, and QD3=3.1 eV, and the ionization potentials of the quantum dots are 5.2 eV, 5.6 eV, and 5.8 eV, the electron affinity QD2=3.3 eV of the second quantum dot 3 having a shorter emission wavelength becomes larger than the electron affinity QD1=3.2 eV of the first quantum dot 2 having a longer emission wavelength.

### Second Embodiment

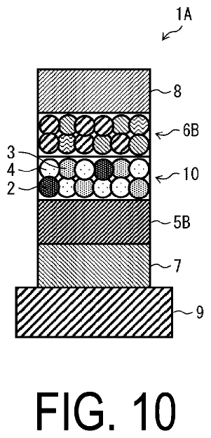

FIG. 10 is a cross-sectional view of a light-emitting element 1A according to a second embodiment. The same constituent elements as the constituent elements described above are denoted by the same reference numerals and signs, and detailed descriptions thereof are not repeated.

A cathode 7, an electron transport layer 5B, a light-emitting layer 10, a hole transport layer 6B, and an anode 8 are provided in this order on a substrate 9. The light-emitting layer 10 includes first quantum dots 2, second quantum dots 3, and third quantum dots 4 having different ionization potentials.

The cathode 7 includes a conductive material and is electrically connected to the electron transport layer 5B.

The anode 8 includes a conductive material and is electrically connected to the hole transport layer 6B.

At least one of the cathode 7 and the anode 8 is constituted by a transparent conductive film. As the transparent conductive film, for example, ITO, IZO, ZnO, AZO, BZO, and the like, or Ag, Al, Cu, Au, and the like formed into thin layers, nanoparticles, or nanowires are used. The transparent conductive film is formed by a sputtering method, vapor deposition, coating, or the like.

Either one of the cathode 7 and the anode 8 may be formed of a metal. The metal is preferably Al, Cu, Au, or Ag having a high reflectivity of visible light.

The electron transport layer 5B is formed of an n-type oxide semiconductor (for example, ZnO, Zn₁₋ₓMgₓO (0≤X<1), TiO₂, and SnO₂). The electron transport layer 5B may be nanoparticles or a continuous film. The electron transport layer 5B can be formed by coating, a sputtering method, vapor deposition, or the like.

The hole transport layer 6B is a mixture of nanoparticles having two or more different ionization potentials, and is formed of an inorganic compound, whereby it is possible to increase the reliability of the light-emitting element 1A.

The hole transport layer 6B is, for example, a mixture of nanoparticles of Ni₁₋ₓMgₓO (0≤x<1), in which x=0, 0.25, and 0.5 and an average particle size of the nanoparticles is 12 nm. The ionization potentials are 5.4 eV, 5.6 eV, and 5.8 eV, respectively.

In order to impart different ionization potentials to the hole transport layer 6B, different materials such as Cu₂O, NiO, and NiO₁₋ₓ(LaNiO₃)ₓ may be used for the hole transport layer 6B. Nanoparticles of each material are prepared by a known technique, and a mixed solution in which the nanoparticles are mixed in an organic solvent such as ethanol is used to form the hole transport layer 6B using a spin coating method, an ink-jet method, or the like.

In the present embodiment, the light-emitting layer 10 includes first quantum dots 2 of red light (ionization potential of 5.4 eV) in which a core material is InP, second quantum dots 3 of green light (ionization potential of 5.6 eV) in which a core material is CdSe, and third quantum dots 4 of blue light (ionization potential of 5.8 eV) in which a core material is ZnSe.

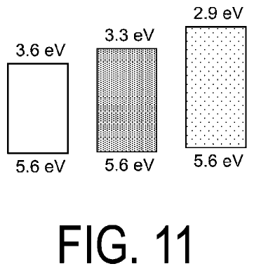

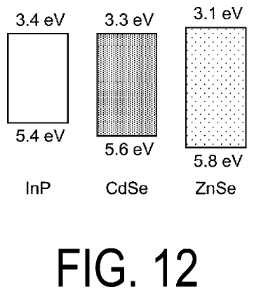

FIG. 11 is a diagram illustrating an electron level of the light-emitting layer provided in the light-emitting element 1 according to the first embodiment. FIG. 12 is a diagram illustrating an electron level of the light-emitting layer provided in the light-emitting element 1A according to the second embodiment.

In the first embodiment, quantum dots that emit light of different colors have different electron affinities, and thus the electron transport layer 5 includes nanoparticles having different electron affinities. When materials of core portions of the quantum dots are the same, the ionization potentials are substantially the same. On the other hand, in the second embodiment, the hole transport layer 6B includes nanoparticles having different ionization potentials for quantum dots having different ionization potentials. The ionization potential of the quantum dot varies depending mainly on the core material. As illustrated in FIG. 12, for example, when the core material is CdSe, the ionization potential is approximately 5.6 eV, when the core material is InP, the ionization potential is approximately 5.4 eV, when the core material is ZnSe, the ionization potential is approximately 5.8 eV, and when the core material is InN, the ionization potential is approximately 6.5 eV.

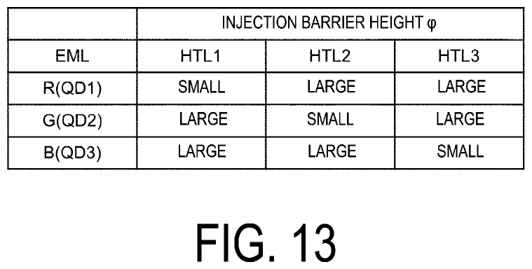

FIG. 13 is a diagram illustrating injection barriers of holes from the hole transport layer 6B to the first quantum dots 2, the second quantum dots 3, and the third quantum dots 4. The hole injection into the quantum dots can be described in the same manner as in the electron injection of the electron transport layer 5. A magnitude relationship of an injection barrier height is as illustrated in FIG. 13.

Compared to a case where the hole transport layer 6 that includes a single ionization potential is used, holes can be injected into each of the first quantum dot 2, the second quantum dot 3, and the third quantum dot 4 at an appropriate low voltage in the hole transport layer 6B including nanoparticles having different ionization potentials. Thus, by appropriately selecting and mixing nanoparticles having an ionization potential that increases injection efficiency for each of the first quantum dot 2, the second quantum dot 3, and the third quantum dot 4, it is possible to obtain the light-emitting element 1A having high luminous efficiency.

For this reason, it is preferable that the hole transport layer 6B have ionization potentials differing by the same types as the core materials of the quantum dots, and, when the ionization potential of the first quantum dot 2 is set to be QD1, the ionization potential of the second quantum dot 3 is set to be QD2, the ionization potential of the third quantum dot 4 is set to be QD3, the ionization potential of a first material of the hole transport layer 6B is set to be HTL1, the ionization potential of a second material of the hole transport layer 6B is set to be HTL2, and the ionization potential of a third material of the hole transport layer 6B is set to be HTL3 in ascending order of the ionization potentials of the quantum dots, it is preferable that HTL1≤QD1<HTL2≤QD2<HTL3≤QD3. Holes can be injected from the hole transport layer 6B suitable for the quantum dots, and the luminous efficiency of the light-emitting element 1A can be increased.

In addition, for every 0.1 eV difference in ionization potential, the ease of injection of a current varies by approximately 50 times, and thus a difference in ionization potential between the nanoparticles of the first material, the second material, and the third material is preferably 0.1 eV or more. A current can be preferentially applied to suitable quantum dots among the first quantum dots 2, the second quantum dots 3, and the third quantum dots 4.

In Ni₁₋ₓMgₓO, the larger the value of the composition x, generally, the larger the ionization potential, so carrier concentration is lower and resistivity is higher. By increasing the volume ratio of nanoparticles having a large ionization potential, the conductivity of the nanoparticles having a large ionization potential can be improved, and the luminous efficiency of a color having a lower luminous efficiency can be improved, so that it is possible to increase the overall luminous efficiency in a well-balanced manner. In addition, holes are easily injected into nanoparticles having a small ionization potential from the anode 8, and thus it is preferable that the nanoparticles having a small ionization potential have the largest volume ratio in the vicinity of the interface between the anode 8 and the hole transport layer 6B. Thereby, holes are easily injected into the hole transport layer 6B from the anode 8.

The volume ratio of nanoparticles having a small ionization potential may be 100% in the vicinity of the interface described above.

In this manner, the light-emitting element 1A includes the light-emitting layer 10 including the first quantum dots 2 that emit red light having a first wavelength and the second quantum dots 3 that emit green light having a second wavelength different from the first wavelength, and the hole transport layer 6B that supplies holes to the first quantum dots 2 and the second quantum dots 3.

The hole transport layer 6B includes a mixture of the first material and the second material. The ionization potential of the first quantum dot 2 is equal to or larger than the ionization potential of the first material. The ionization potential of the second material is larger than the ionization potential of the first material. The ionization potential of the second quantum dot 3 is equal to or larger than the ionization potential of the second material.

It is preferable that the light-emitting element 1A further include the third quantum dots 4 that emit blue light having a third wavelength different from the first wavelength and the second wavelength.

It is preferable that the third material be further mixed into the mixture of the hole transport layer 6B. Thereby, it is possible to realize the hole transport layer 6B having three types of ionization potentials.

It is preferable that the ionization potential of the third material be larger than the ionization potential of the second material, and the ionization potential of the third quantum dots 4 be equal to or larger than the ionization potential of the third material. Thereby, holes can be injected from the material of the hole transport layer 6B having an ionization potential suitable for the quantum dots, and the luminous efficiency can be increased.

It is preferable that the ionization potential of the first quantum dot 2 and the ionization potential of the second quantum dot 3 be different from each other. Thereby, luminous efficiency can be increased by the hole transport layer 6B.

It is preferable that the material of the first quantum dot 2 and the material of the second quantum dot 3 be different from each other. Thereby, the ionization potential of the first quantum dot 2 and the ionization potential of the second quantum dot 3 can be made different from each other.

When the ionization potential of the first quantum dot 2 is smaller than the ionization potential of the second quantum dot 3, it is preferable that the ionization potential of the first material be equal to or smaller than the ionization potential of the first quantum dot 2, the ionization potential of the first quantum dot 2 be smaller than the ionization potential of the second material, and the ionization potential of the second material be equal to or smaller than the ionization potential of the second quantum dot 3. Thereby, the luminous efficiency of each of the first quantum dot 2 and the second quantum dot 3, which have mutually different ionization potentials, can be increased by the hole transport layer 6B including the mixture of the first material and the second material.

It is preferable that the first material and the second material include nanoparticles. Thereby, it is possible to realize the hole transport layer 6B having a plurality of types of ionization potentials by varying the composition and material of the nanoparticles.

It is preferable that the first material and the second material include nanoparticles, be composed of Ni₁₋ₓMgₓO (0≤x<1), and have mutually different compositions (x). Thereby, it is possible to realize the hole transport layer 6B having a plurality of types of ionization potentials by varying the composition (x) of Ni₁₋ₓMgₓO (0≤x<1) between the first material and the second material.

The first material, the second material, and the third material include nanoparticles, and it is preferable that the volume ratios of the first material, the second material, and the third material included in the hole transport layer 6B become larger in descending order of the ionization potentials thereof. Thereby, it is possible to improve the luminous efficiency more easily for a color having a lower luminous efficiency by facilitating the injection of holes into nanoparticles having a large ionization potential.

The first material, the second material, and the third material include nanoparticles, and it is preferable that the volume ratios of the first material, the second material, and the third material included in the hole transport layer 6B become larger in ascending order of the ionization potentials of the first material, the second material, and the third material in the vicinity of the interface with the anode 8. Thereby, holes are easily injected into the hole transport layer 6B from the anode 8.

The first material, the second material, and the third material include nanoparticles, and it is preferable that the volume ratios of the first material, the second material, and the third material included in the hole transport layer 6B become larger in descending order of the ionization potentials of the first material, the second material, and the third material in the vicinity of the interface with the light-emitting layer 10. Thereby, it is possible to improve the luminous efficiency more easily for a color having a lower luminous efficiency by facilitating the injection of holes into nanoparticles having a large ionization potential.

The first material, the second material, and the third material include nanoparticles, and it is preferable that the nanoparticles having the smallest ionization potential among the first material, the second material, and the third material decrease in size from the anode 8 side toward the light-emitting layer 10 side. Thereby, there is no obstacle to holes being injected in the order of the first material, the second material, and the third material in a direction in which the holes flow, and a voltage in the hole transport layer 6B can be minimized.

It is preferable that the amount of nanoparticles other than the nanoparticles having the smallest ionization potential increase toward the light-emitting layer 10 side. Thereby, there is no obstacle to holes being injected in the order of the first material, the second material, and the third material in a direction in which the holes flow, and a voltage in the hole transport layer 6B can be minimized.

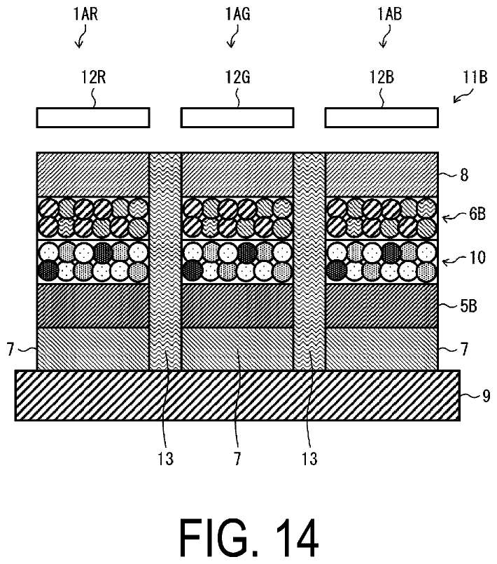

FIG. 14 is a cross-sectional view of a display device 11B using the light-emitting element 1A according to the second embodiment. The same constituent elements as the constituent elements described above are denoted by the same reference numerals and signs, and detailed descriptions thereof are not repeated.

As illustrated in FIG. 14, the display device 11B includes a plurality of light-emitting elements 1AR, 1AG, and 1AB, and color filters 12R, 12G, and 12B in the light-emitting directions of the respective light-emitting elements 1AR, 1AG, and 1AB. The color filters 12R, 12G, and 12B are filters that transmit only wavelengths of specific colors of light emitted from the light-emitting elements 1AR, 1AG, and 1AB. More specifically, the color filter 12R transmits only red light, the color filter 12G transmits only green light, and the color filter 12B transmits only blue light. The light-emitting elements 1AR, 1AG, and 1AB may or may not be separated from each other by side walls 13 as illustrated in FIG. 14.

Although an example in which the side walls 13 pass from the anode 8 to the cathode 7 to be able to separate the adjacent light-emitting elements 1AR and 1AG or 1AG and 1AB is shown, the disclosure is not limited thereto, and it is only required that the side walls 13 be formed being able to separate the adjacent cathodes 7 from each other.

Although an example in which the light-emitting layer 10 includes the first quantum dots 2, the second quantum dots 3, and the third quantum dots 4 has been described, the disclosure is not limited thereto. For example, the disclosure can also be applied to an organic light-emitting diode (OLED).

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element comprising:
a light-emitting layer including a mixture of a first light-emitting material configured to emit light having a first wavelength and a second light-emitting material configured to emit light having a second wavelength different from the first wavelength; and
an electron transport layer,
wherein the electron transport layer includes a first material having a first particle size distribution and a second material having a second particle size distribution different from the first particle size distribution, includes a first material and a second material that are composed of A₁₋ₓBₓC (0≤x<1, and A, B, and C are a first element, a second element, and a third element being different from each other) and have mutually different compositions (x), or includes a first material and a second material having mutually different constituent elements,
an electron affinity of the first light-emitting material is equal to or smaller than an electron affinity of the first material,
an electron affinity of the second material is smaller than the electron affinity of the first material, and
an electron affinity of the second light-emitting material is equal to or smaller than the electron affinity of the second material.

2. The light-emitting element according to claim 1,
wherein the electron affinity of the first material and the electron affinity of the second material included in the electron transport layer are different from each other by 0.1 eV or more.

3. The light-emitting element according to claim 1,
wherein the first material and the second material of the electron transport layer each include an inorganic compound.

4. The light-emitting element according to claim 1,
wherein the first material and the second material are composed of Zn₁₋ₓMgₓO (0≤x<1) and have mutually different compositions (x).

5. The light-emitting element according to claim 1,
wherein a combination of the first material and the second material having mutually different constituent elements includes two different combinations selected from (1) at least one selected from TiO₂ and SnO₂, (2) at least one selected from GaP, AlSb, and ZrO₂, and (3) at least one selected from GaN, ZnS, ZnTe, Ca₂SnO₄, and CaSnO₃.

6. The light-emitting element according to claim 1,
wherein a third light-emitting material configured to emit light having a third wavelength different from the first wavelength and the second wavelength is further mixed into the mixture of the light-emitting layer,
the electron transport layer is further mixed with a third material having a third particle size distribution different from the first particle size distribution and the second particle size distribution, a third material composed of A₁₋ₓBₓC (0≤x<1) and having a composition (x) different from the composition (x) of the first material and the composition (x) of the second material, or a third material having a constituent element different from the constituent element of the first material and the constituent element of the second material, and
an electron affinity of the third material is smaller than the electron affinity of the second material, and an electron affinity of the third light-emitting material is equal to or smaller than the electron affinity of the third material.

7. The light-emitting element according to claim 1,
wherein the first material, the second material, and the third material of A₁₋ₓBₓC (0≤x<1) are composed of Zn₁₋ₓMgₓO (0≤x<1) and have mutually different compositions (x).

8. (canceled)

9. The light-emitting element according to claim 1,
wherein the electron affinity of the first light-emitting material and the electron affinity of the second light-emitting material are different from each other.

10. The light-emitting element according to claim 1,
wherein, when the electron affinity of the first light-emitting material is equal to or larger than the electron affinity of the second light-emitting material, the electron affinity of the first material is equal to or larger than the electron affinity of the first light-emitting material, the electron affinity of the first light-emitting material is equal to or larger than the electron affinity of the second material, and the electron affinity of the second material is equal to or larger than the electron affinity of the second light-emitting material.

11. The light-emitting element according to claim 1,
wherein the first material and the second material include nanoparticles.

12. The light-emitting element according to claim 6,
wherein the first material, the second material, and the third material include nanoparticles, and
volume ratios of the first material, the second material, and the third material included in the electron transport layer become larger in ascending order of the electron affinities of the first material, the second material, and the third material.

13-16. (canceled)

17. The light-emitting element according to claim 6,
wherein the first material, the second material, and the third material include nanoparticles and are composed of ZnO,
an average particle size of the nanoparticles of the first material is 4.5 nm or more,
an average particle size of the nanoparticles of the second material is 3.5 nm or more and less than 4.5 nm, and
an average particle size of the nanoparticles of the third material is 2.8 nm or more and less than 3.5 nm.

18. The light-emitting element according to claim 6,
wherein the first material, the second material, and the third material each include nanoparticles composed of Zn₁₋ₓMgₓO,
the nanoparticles of the first material satisfy 0≤x<0.15,
the nanoparticles of the second material satisfy 0.15<x≤0.3, and
the nanoparticles of the third material satisfy 0.3<x≤0.5.

19. (canceled)

20. A light-emitting element comprising:
a light-emitting layer including a mixture of a first light-emitting material configured to emit light having a first wavelength and a second light-emitting material configured to emit light having a second wavelength different from the first wavelength; and
an electron transport layer,
wherein the electron transport layer includes a first material having a first particle size distribution and a second material having a second particle size distribution different from the first particle size distribution, includes a first material and a second material that are composed of Zn₁₋ₓMgₓO (0≤x<1) and have mutually different compositions (x), or includes a combination of a first material and a second material having mutually different constituent elements, and
the combination of the first material and the second material having mutually different constituent elements includes two different combinations selected from (1) at least one selected from TiO₂ and SnO₂, (2) at least one selected from GaP, AlSb, and ZrO₂, and (3) at least one selected from GaN, ZnS, ZnTe, Ca₂SnO₄, and CaSnO₃.

21. A light-emitting element comprising:
a light-emitting layer including a mixture of a first light-emitting material configured to emit light having a first wavelength and a second light-emitting material configured to emit light having a second wavelength different from the first wavelength; and
a hole transport layer,
wherein the hole transport layer includes a first material and a second material,
an ionization potential of the first light-emitting material is equal to or larger than an ionization potential of the first material,
an ionization potential of the second material is larger than the ionization potential of the first material, and
an ionization potential of the second light-emitting material is equal to or larger than the ionization potential of the second material.

22. The light-emitting element according to claim 21,
wherein a third light-emitting material configured to emit having a third wavelength different from the first wavelength and the second wavelength is further mixed into the mixture of the light-emitting layer,
the hole transport layer further includes a third material,
an ionization potential of the third material is larger than the ionization potential of the second material, and
an ionization potential of the third light-emitting material is equal to or larger than the ionization potential of the third material.

23. The light-emitting element according to claim 21,
wherein the ionization potential of the first light-emitting material and the ionization potential of the second light-emitting material are different from each other.

24. The light-emitting element according to claim 21,
wherein a material of the first light-emitting material and a material of the second light-emitting material are different from each other.

25-32. (canceled)

33. The light-emitting element according to claim 1,
wherein the first light-emitting material is a first quantum dot, and
the second light-emitting material is a second quantum dot.

34-35. (canceled)

36. The display device comprising:
a plurality of the light-emitting elements according to claim 1, further comprising:
a plurality of color filters that transmit light having different wavelengths in the light-emitting element.
